(19) United States
(12) Patent Application Publication
(10) Pub. No.: US 2022/0275513 A1
(43) Pub. Date: Sep. 1, 2022

(54) METHOD FOR PRODUCING COATINGS WITH ADAPTED COATING PROPERTIES

(71) Applicant: Oerlikon Surface Solutions AG, Pfäffikon, Pfäffikon (CH)

(72) Inventor: Marijana Mionic EBERSOLD, Dübendorf (CH)

(21) Appl. No.: 17/627,798

(22) PCT Filed: Jul. 17, 2020
(86) PCT No.: PCT/EP2020/070375

§ 371 Date: Jan. 17, 2022

Related U.S. Application Data
(60) Provisional application No. 62/875,077, filed on Jul. 17, 2019.

(51) Int. Cl. C23C 16/50

(52) U.S. Cl. CPC C23C 16/50

(57) ABSTRACT

Method for producing coating materials by conducting at least following two steps: —a first step in which a coating layer of a first material is synthesized on the surface of a substrate to be coated, wherein the coating layer is produced by using a vapor deposition method, at a first temperature T₁, wherein T₁ is preferably a temperature not higher than 500° C., and —a second step conducted after the first step, in which the coating layer of the first material deposited in the first step, is exposed to an specific high energy, wherein the specific high energy to be delivered to the substrate is selected in order to produce the same or an equivalent effect as it, which would be attained if the coating layer were produced at a second temperature T₂, wherein T₂ is higher than T₁ and preferably T₂ is a temperature above 500° C. or more preferably above 600° C. or even above 1000° C.

The present invention relates to a new method for producing coatings, especially thin films.

In the context of the present invention the term “thin films” is used for referring to coating films having film thickness in nanometers and/or micrometers range.

Commonly different vapor deposition methods are used for producing thin films for improving surface properties of tools and components.

However, it remains a challenge to produce coatings exhibiting all desired coating properties in one process when high temperatures are required for the synthesis of the coatings.

In other words, since some materials to be synthesized as coatings need to be processed at temperatures above 500° C. or above 600° C. and sometimes even above 1000° C. in order to develop the wished coating properties, it is commonly necessary that at least the surfaces of the substrates at which such materials should be synthesized, be processed to the necessary high process temperature (above 500° C. or above 600° C. or even above 1000° C.).

However, it is not always so that the substrates to be coated (in the context of the present description also called parts to be coated) are made of materials or comprise materials that can withstand such high process temperatures.

Likewise, sometimes even the material of the coating chamber or the material of some parts of the coating chamber cannot withstand such high process temperatures.

In such cases in which temperature sensible materials are present in the substrates to be coated and/or in parts of the coating chamber, the necessary process temperature cannot be attained because heating of the temperature sensible materials till such high temperatures can cause damages to the substrates and/or to parts of the coating chamber, respectively.

### Objective of the Present Invention

One of the objectives of the present invention is to provide an alternative method which allows to overcome the above described problems of the state of the art.

In particular, the present invention should provide a method that allows processing of coatings, which avoid typical heating of the substrates to be coated for attaining the necessary high process temperature that is usually necessary for producing some materials with particular properties.

One further objective of the present invention is to provide a new method for producing coatings, in particular thin films, exhibiting a predefined set of desired coating parameters.

### DESCRIPTION OF THE PRESENT INVENTION

The objective of the present invention is attained by providing a new method for producing coating materials by conducting at least following two steps:
a first step in which a coating layer of a first material is synthesized on the surface of a substrate to be coated, wherein the coating layer is produced by using a conventional method, preferably a vapor deposition method, e.g. a physical vapor deposition method or a chemical vapor deposition method (or a plasma assisted chemical vapor deposition method) or a combination thereof, at a first temperature T₁, wherein T₁ is preferably a temperature not higher than 500° C. or preferably not higher than 600° C. or preferably even not higher than 1000° C., and
a second step conducted after the first step, in which the coating layer of the first material deposited in the first step, is exposed to an specific high energy by irradiating said coating layer of the first material, by using a pulsed radiation source, preferably one or more flashlamps, wherein the specific high energy to be delivered to the substrate is selected in order to produce the same or an equivalent effect as it, which would be attained if the coating layer were produced at a second temperature T₂, wherein T₂ is higher than T₁ and preferably T₂ is a temperature above 500° C. or preferably above 600° C. or preferably even above 1000° C.

The objective of the present invention is attained by providing a method comprising at least following two process steps:
a) Deposition of a coating on a substrate surface within a coating deposition chamber (usually a vacuum coating chamber), said coating comprising at least one coating layer 1 made of a first material M₁ (exhibiting a set of physical and chemical properties which will be hereafter respectively called P_{f1} (for identifying the set of physical properties of the coating layer 1 made of M₁) and P_{ch1} (for identifying the set of chemical properties of the coating layer 1 made of M₁) corresponding to the as deposited state) deposited by using a vapour deposition process (hereafter also referred to as VD), such as a physical vapor deposition process (hereafter also referred to as PVD) and/or a chemical vapor deposition process and/or a plasma assisted chemical vapor deposition process (hereafter also referred to as CVD or PA-CVD, respectively).
b) Thermal treatment (it means energy input by irradiation) of the coating or at least of the at least one coating layer 1 outside of the coating deposition chamber (depending of the equipment used for conducting this step, the process can be conducted for example in ambient air, in vacuum, in vacuum under inert gas, in vacuum under nitrogen gas or in vacuum under any other available gas) by using at least one lamp of the type radiation source, preferably a pulsed radiation source (hereafter also called arc lamp or simply lamp), preferably a plasma arc lamp or an electric arc lamp (these kinds of lamps are also commonly called flashlamps or flashtubes), wherein for applying this irradiation at least one lamp operated in pulses for modifying the properties of the at least one coating layer 1 (made of a first material M₁ as mentioned above) deposited in the process step a), producing in this manner a thermal processed coating exhibiting properties (exhibiting a set of physical and chemical properties which will be hereafter respectively called P_{f2} (for identifying the set of physical properties of the coating layer 2 made of M₂) and P_{ch2} (for identifying the set of chemical properties of the coating layer 2 made of M₂) corresponding to the as deposited state)) that are different from the properties of the coating deposited in the process step a) (i.e. the coating material resulting after process step b) possesses properties that differs from the properties of the coating material deposited in the process step a). Preferably the coating layer 1 made of the first material M₁ completely turns into the coating layer 2 made of the second material M₂, preferably after the second process step, in particular after the thermal treatment. The second materiel M₂ preferably differs from the first material M₁ at least in set of physical properties or at least in the set of chemical properties, so that P_{f1}≠P_{f2} P₂ and/or P_{ch1}≠P_{ch2}, in particular so that P_{f1}≠P_{f2} and/or P_{ch1}≠P_{ch2}.

The process step b) is conducted for inducing one or more changes in one or more physical and/or chemical properties of the coating deposited in the process step a).

The thermal treatment in step b) in the present invention does not refer a standard heating process conducted by ovens or heaters, which are done either by conventional or convection ovens or heaters. The thermal treatment in step b) in the present invention is conducted as explained above by using a radiation source, e.g. a radiant heater, which heats by using photons. It means, in the present invention the thermal treatment should be understood as a heating by photons from the arc lamp (also called flashlamp or flashtube).

More specifically an appropriate radiation source in the present invention is one or more arc lamps, preferably plasma arc lamps and/or electric arc lamps (these kinds of lamps are also commonly called flashlamps or flashtubes). Such lamps produce incoherent full-spectrum white extremely intense light for very short durations. Thus such lamps can deliver very high energies in the form of the short pulses. Therefore such a lamp can also be called a pulsed radiation source. Such lamps are in the use in for instance photographic applications, as well as in entertainment industry, medical, scientific applications. From recently such lamps are also used in the field of printed electronic industry in the process of sintering nanomaterials on the temperature sensitive substrates by exposing it to the flashlamps. Since in this way nanomaterials are exposed to heating by photons from the flashlamps, such process is often called photonic curing as described for example by Schroder et al. in the patent document U.S. Pat. No. 7,820,097B2 or in the article “Mechanisms of Photonic Curing: Processing High Temperature Films on Low Temperature Substrates” published in Nanotechnology, 2011—novacentrix.com.

However, using such a lamp for inducing a transformation of a coating material M₁ deposited by using a vapor deposition process into a new material M₂ having different physical and/or chemical properties as compared to those of material M₁ was unexpected.

Interestingly, photons can carry different energies and when photons hit a surface material, they can penetrate that material depending on their energy and on the properties of that material only very close to that surface in the depth in nanometers or very few micrometers range. Surprisingly, such photons could be placed to interact with coating films having thickness in nanometers and/or micrometers range till attaining the necessary high energies for producing the desired coating properties, in other words, for transforming the material M₁ into the material M₂.

In this manner the inventor has attained that desired coating properties, which otherwise can only be obtained by heating the substrate till attaining high process temperatures of above 500° C. or preferably above 600° C. or preferably even sometimes above 1000° C.

The above mentioned changes of the coating properties (in other words: transformations of the coating material originally deposited) are attained by choosing the suitable lamp's operating parameters (for instance lamp properties, such as wavelength, intensity, flux, all pulse properties, such as pulse length, intensity, waiting time in-between the pulses etc.) after considering the required properties that need to have the coating deposited in the process step a) (such as coating thickness, refractive index of the coating material, absorbance of the coating material for the wavelength of our choice) in order to obtain the desired transformations.

For conducting the step b) in the inventive examples described afterwards, the inventor decided to use an equipment called PulseForge®1300 comprising a flashlamp, designed for photonic curing, manufactured by the company Novacentrix.

The properties of such type of equipment containing flashlamps will be given on the example of PulseForge®1300 from the company Novacentrix equipped with xenon flash lamps:

| | |
|---|---|
| Peak radiant power delivered (kW/cm²) | 35 |
| Max radiant energy delivered (J/cm²) | 100 |
| Max voltage to lamp(s) | 950 |
| Effective max linear processing speed (meters/min) | 30 |
| Curing dimension per pulse (mm) | 75 × 150 |
| Max area cured per sample (mm) | 300 × 150 |
| Pulse length range (microseconds) | 25-100,000 |
| Pulse length increment (microseconds) | 1 |
| Minimum pulse spacing (microseconds) | 20 |
| Max pulse rate | >kHz |
| Output spectrum (nm) | 200-1500 |

By selecting values of the above mentioned parameters, the process step b) can be designed in such a manner that it delivers via photons from flashlamp the energy input to the material M₁ which is needed to induce the desired changes of properties of the material M₁ in order to transform it into the material M₂.

The energy input which is needed for this purpose (the desired transformation) will be calculated depending on a large number of parameters of both the equipment that will be used and the material M₁ of the coating layer 1 itself. Thus, calculating the exact energy input which is needed in every single case can be a very complex process.

Therefore, such kind of equipment, typically has a suitable software which can simulate temperature to which the material to be irradiated would be exposed when the material is processed (irradiated) by using the flashlamp. As an example, the equipment PulseForge®1300 from the company Novacentrix is equipped with the software SimPulse Thermal Simulation. This software uses determined properties of the material to be exposed to irradiation (in the context of the present invention: material M₁) and the selected process parameters for the operation of the flashlamp to calculate the temperature and the energy to which the material M₁ would be exposed during the process of applying irradiation with the flashlamp.

The mentioned properties that need to be known from the material to be treated in the step b) (in this case material M₁) depends from the equipment and the respective software but are for example thickness (μm), thermal conductivity (W/mK), density (g/cm3), molar mass (g/mol), melting temperature (° C.), etc.

As explained above, this equipment was used for carrying out some examples of the invention, but the present invention is not limited to the use of this equipment. This equipment is only one example of an equipment with a lamp for carrying out a process step b) for the conduction of a method according to the present invention.

This new inventive method allows producing new desired coating properties in coatings being already deposited on substrates (such as but not limited to cutting tools, forming tools, as well as parts, such as turbine parts, semiconductor industry parts, car industry parts, medical devices parts etc.).

A big advantage of this new inventive method is the possibility of a flexible adjustment or generation of new material properties at the surface of already coated substrates without affecting substrate material and without being limited by the substrate material and/or the materials of VD chamber.

Some of these coating properties that can be changed in the process step 2) of the present inventive method are for example:
grain: size, chemical element composition, plane orientation;
compressive and/or tensile stress;
grain boundaries: thickness, crystalline structure, chemical composition;
coating: hardness, Young's modulus, roughness, wear resistance, oxidation resistance, scratch resistance, thermal stability (e.g. chemical stability at high temperatures), corrosion resistance, chemical composition, crystallinity, chemical and/or crystalline structure.

In order to attain a better understanding of the present invention, some examples of coatings produced according to the present invention will be described. The changes of coating properties regarding crystallinity during the conduction of an inventive method as described in the Examples 1 and 2 are shown in the FIGS. 1 and 2, respectively. This examples should be understood only as showcases of the invention and not as any limitation of the invention.

### FIGURE CAPTIONS

FIG. 1: XRD of aluminium oxides coating layers produced after conducting a first step (process step a)) and after conducting a second step (process step b)) for producing an alfa crystalline aluminium oxide coating as described by using a method according to the present invention as described in Example 1.

FIG. 2: XRD of aluminium oxides coating layers produced after conducting a first step (process step a)) and after conducting a second step (process step b)) for producing an alfa crystalline aluminium oxide coating as described by using a method according to the present invention as described in Example 2.

The process parameters used for operating the arc lamp for the conduction of the second step (process step b)) in the inventive methods described in the Examples 1 and 2 are shown in Table 1.

TABLE 1
Overview of the pulse parameters and operation parameters
used for operating the arc lamp for the conduction
of the process step b) in the described Examples 1
and 2 (the step b) was conducted in both cases in air):

| | | Example 1 | Example 2 |
|---|---|---|---|
| Pulse | energy per count [J/cm²] | 10.2 | 19.9 |
| | shape | sinusoidal | sinusoidal |
| | voltage [V] | 800 | 850 |
| | μPulses | 3 | 5 |
| | Envelope [μs] | 1300 | 2300 |
| | Number of shots | 26M | 2.9M |
| Operation | Fire rate [Hz] | 3.1 | 0.1 |
| | Repeat count | 100 | 50 |
| | Duty cycle [%] | 50 | 50 |
| | Simulated maximal | 1250 | 578 |
| | Temperature at surface [° C.] | | |
| | Total energy per all counts | 1020 | 995 |
| | [J/cm²] | | |

### Inventive Example 1: Synthesis 1 of Alfa Crystalline Aluminium Oxide

An amorphous aluminium oxide coating either non-doped or doped with other chemical elements (such as metal or metalloids) can be easily deposited by using for instance a physical vapor deposition process. Such an amorphous aluminium oxide coating can be easily deposited on different substrate materials, such as steel. The substrate material can be any material allowing the use of the chosen vapor deposition process. Hence in order to produce a crystalline aluminium oxide coating by using a method according to the present invention, a first process step a) is carried out, in which aluminium oxide is deposited in amorphous state by using a VD process.

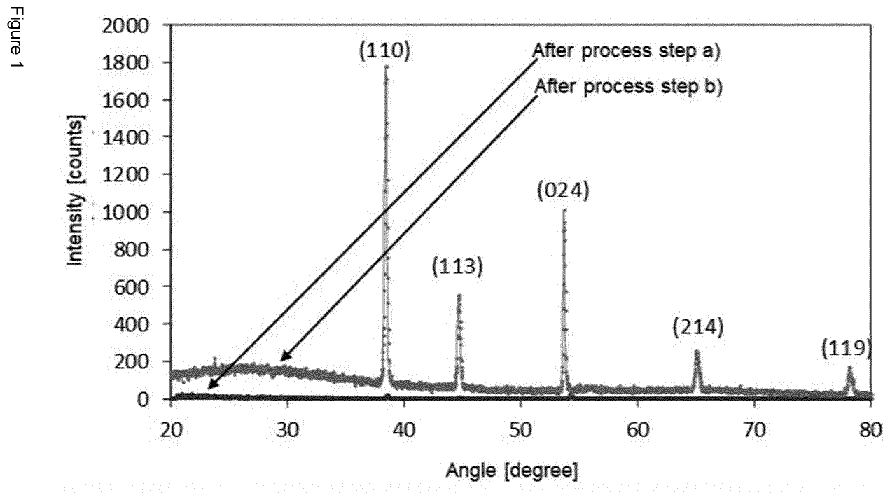

The amorphous aluminium oxide coating layer in this example was deposited by PVD (in a known manner) on Si wafer. The total coating layer thickness was 3.7 μm. This coating layer was examined with the step size 0.02° on a laboratory X-ray diffractometer using Cu Kα radiation model Discover D8 from Bruker. The resulting diffractogram (XRD diffractogram) is shown in FIG. 1. The corresponding diffractogram (black plotted line) indicates no characteristic peaks of any of the aluminium oxides, meaning that the “as deposited” coating is amorphous.

After producing the substrate coated with amorphous aluminium oxide in this manner, the coating deposited on the coated substrate was subjected to a thermal treatment in a second process step b) according to the present invention.

The equipment used in this example PulseForge®1300 from the company Novacentrix containing xenon flash lamp. PulseForge®1300 was equipped with software Sim Pulse for thermal simulation. The combination of the process parameters were optimized in such way that with this process we can induce desired change of the physical and/or chemical properties of the material M₁ after step (a). For instance the starting material for this Example as after step (a) is amorphous alumina. Amorphous alumina is soft material, which has no benefits in use as protective coating. However, crystalline alumina is well known to be versatile material, which has lot of different crystalline phases, such as alfa, beta, gamma, delta, etc. However for the wear resistance applications like hard coating the most beneficial is corundum phase, alfa alumina. But desired corundum phase require large energy for phase transformation and thus corundum can be obtained only in the specific conditions. If one could have alumina in corundum phase that would be highly desired material for hard coatings because of high oxidation resistance, high wear resistance, temperature stability, etc.

This mentioned energy required for phase transformation of amorphous into crystalline alumina with exactly corundum phase regardless a crystalline orientation of the corundum crystals is typically delivered to the material as thermal energy. Numerous publications indicates that the required high temperature range to obtained corundum is from 900° C. to 1200° C. Therefore, the combination of process parameters for using flashlamps needs to be optimized in such way that material with given thickness and properties can receive energy in the sufficient amount and in the suitable way which can induce transformation of amorphous alumina into crystalline alumina with the exactly desired corundum phase.

Thus, the combination of process parameters was adjusted in such way that the process creates really energy via temperature in the required range in order to transform amorphous alumina into corundum.

The optimized combination of process parameters used for operating the arc lamp for conducting the process step (b) is given in Table 1 (Example 1). The software SimPulse simulated temperature in the coating to be up to 1250° C. with the chosen combination of the process parameters.

Indeed after applied the second process step, the previously amorphous material without any characteristic XRD peak was transformed into crystalline alumina displaying numerous characteristic peaks of aluminium oxide, indicating a partially corundum crystalline structure (grey plotted line with characteristic peaks shown in FIG. 1).

In this manner the amorphous aluminium oxide coating deposited in process step a) was transformed into crystalline aluminium oxide in process step b) according to the present invention.

The big advantage of the inventive method in this example is that the previously amorphous coating could be transformed in partially crystalline aluminium oxide, in particular in partially corundum crystalline structure without producing any substrate damages by conducting the second process step (b)) according to the present invention.

FIG. 1 shows a both the XRD diffractogram) of a the coating material, i.e. amorphous aluminium oxide produced in the first process step (process step a)). This coating material was analysed in “as deposited” state (black line) and shows not any characteristic peaks, which corresponds to an amorphous material.

After conducting the second process step (process step b)) by applying energy with an arc lamp to the amorphous aluminium oxide coating (by using the arc lamp parameters indicated in Table 1 for Example 1), the coating material deposited in the process step a) was transformed and shows clearly characteristic peaks of highly crystalline aluminium oxide with marked detected peaks (110), (113), (214), (119).

In this example we proved that the inventive method can be used to transform the material M₁ obtained in the step (a) into material M₂ by applying step (b). In this way we had information which energy is necessary to transform exactly our material with the given nature (amorphous alumina) and given properties, such as thickness of 3.7 μm. That energy delivered by flash lamps of PulseForge®1300 in the inventive Example 1 was about 1 kJ/cm² (as given in the Table 1) or more precisely 1020 J/cm², what is a value obtained as product of pulse energy per count (which was in this Example optimized to be 10.2 J/cm²) and total number of courts (which was in this Example chosen to be 100). This discovery was the base for the work in the following inventive Example 2.

### Inventive Example 2: Synthesis of Alfa Crystalline Aluminium Oxide

An amorphous aluminium oxide coating can be easily deposited by using for instance a physical vapor deposition process. Such amorphous aluminium oxide coating can be easily deposited on different substrate materials, such as steel (substrate material can be any material allowing the use of the chosen vapor deposition process) according to the first process step (a)) of a method according to the present invention.

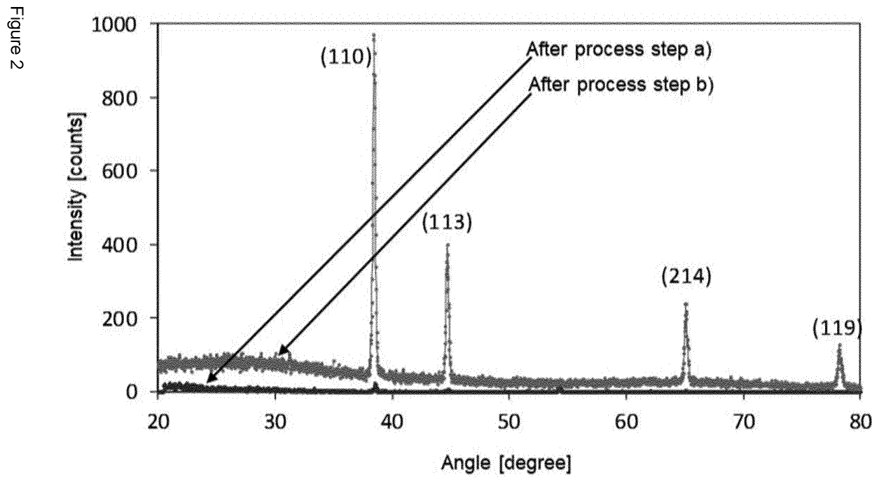

The amorphous aluminium oxide coating in this example was deposited on Si wafer. XRD given in FIG. 2 shows no characteristic peaks of any of aluminium oxides, meaning that “as deposited” coating is amorphous.

After producing the coated substrate in this manner, the coating deposited on the coated substrate was subjected to a thermal treatment according to the second process step (b)) of a method according to the present invention. The detailed process parameters of the process step (b) are given in the Table 1.

As describe above, in the previous inventive Example 1 we already proved that the total energy needed for transformation of amorphous alumina of 3.7 μm into crystalline alumina in the highly desired corundum phase is about 1 kJ/cm². This discovery was used as the base for the process optimization in this inventive Example 2. Namely, the combination of the process parameters was optimized and changed in such way that the total energy is also about 1 kJ/cm². That energy delivered by flash lamps of PulseForge®1300 in the inventive Example 2 was about 1 kJ/cm² (as given in the Table 1) or more precisely 995 J/cm², what is a value obtained as product of pulse energy per count (which was in this Example optimized to be 19.9 J/cm²) and total number of courts (which was in this Example chosen to be 50). Thus, the energy per count is double higher than in the Example 1, but the number of repeated counts is double lower than in the Example 1 (here is 50 while in the Example 1 is 100). In this way, total deliver energy is roughly the same in both examples, but delivered to the material in different way via double more energetic counts and with lower number of counts. Moreover, this energy was delivered with lower frequency as comparing to the frequency used in the Example 1. More precisely, in the Example 2 frequency is 0.1 Hz, while in the Example 1 it is 3.1 Hz. Chosen lower frequency allows to material to “relax” after receiving the higher energy counts in this Example, meaning that this energy delivered in the pulse can dissipate into material while waiting for the next pulse allowing that material receive almost the same total energy without reaching the temperature as high as in example 1. Thus here in the Example 2 temperature is lower (max around 580C) but total delivered energy is the same giving the possibility that material M₁, amorphous alumina, transform into material M₂, crystalline corundum.

After such processing step previously amorphous material without any characteristic XRD peak, indeed display numerous characteristic peaks of aluminium oxide with the partially corundum crystalline structure (characteristic peaks are indicated in the FIG. 2). This confirms, that the method described in the inventive Example 2 indeed transform material M₁, amorphous alumina, transform into material M₂, crystalline corundum.

Surprisingly, crystalline structure of aluminium oxide obtained in the Example 1 and 2 by the use of the different process parameters as given in the Table 1 is different. More precisely, those two crystalline structure differ in the one characteristic peak (as it can be seen by comparing the peaks in FIG. 1 with the peaks in FIG. 2). This selective crystalline orientation within the same crystalline phase was obtained by optimizing process parameters in the step (b) of the inventive method in such way that it affects crystallization process of the chosen material and optimized for the chosen material.

This demonstrate that here proposed inventive method allows not only for transformation of the properties of “as deposited” material, but surprisingly also allows for very selective transformation and for tuning of the final properties of the material after the process step (b).

In this manner the amorphous aluminium oxide coating deposited in process step a) was transformed into crystalline aluminium oxide in process step b) according to the present invention.

FIG. 2: XRD of a coating material given in the Example 2 aluminium oxide after a process step 1 “as deposited” (black plotted line) without characteristic peaks shows amorphous material. Surprisingly, after a process step 2 the same coating material shows clearly characteristic peaks of highly crystalline alfa aluminium oxide with marked detected peaks. Importantly note that (024) was present in the crystalline alfa aluminium oxide obtained in the Example 1, but that it is not present in the crystalline alfa aluminium oxide obtained in the Example 2.

The big advantage of the inventive method in this example is that the previously amorphous coating could be transformed in crystalline aluminium oxide without producing any substrate damages by conducting the second process step (b)) according to the present invention.

### FURTHER EXAMPLES

Apart from alumina, there are also other materials that can be useful as coating materials but which exhibit some desired coating properties only if they are produced during exposition of the substrate surface to high energies that are typically attained by using process temperatures (also called substrate temperatures, in particular when PVD or CVD processes are used) of above 500° C. or preferably above 600° C. or preferably sometimes even above 1000° C., for example: SiO₂, SiN and SiC. This list is not exhaustive. The mentioned materials as well as other materials that can be produced with a method according to the present invention can be produced as non-doped as well as doped materials. In the context of the present invention the term “doped materials” means materials which comprise one or more dopant chemical elements in a total dopant concentration in atomic percentage of 0.1% to 30%. In the context of the present invention dopants are preferably metals such as titanium and/or metalloids such as boron.

It means that a coating produced by using a method according to the present invention, can be for example a SiO₂ coating doped with tungsten, so that the concentration of tungsten in the SiO₂ coating is between 0. 1 at. % to 30 at. %.

For example, according to the present invention an amorphous silicon oxide coating can be deposited on different substrate materials, such as steel (substrate material can be any material allowing the use of the chosen vapor deposition process) according to the first process step (a)) of a method according to the present invention.

For conducting the process step a), this coating can be deposited by using a vapor deposition process. Usually processes that can be used are PVD processes, such as Arc PVD or Sputtering PVD processes, and CVD processes such as plasma assisted (or enhanced) CVD processes (also called PA-CVD or PE-CVD).

After producing the coated substrate in this manner, the coating deposited on the coated substrate must be subjected to a thermal treatment according to the second process step (b) of a method according to the present invention.

In this manner the amorphous silicon coating deposited in process step a) is transformed into crystalline silicon dioxide in process step b) according to the present invention.

The big advantage of the inventive method in this example is that crystalline silicon dioxide cannot be deposited on the substrate by a physical deposition process in an easy manner due to various reasons, such as limited temperature to which this substrate and/or materials of a VD chamber can be exposed. However, advantageously the previously amorphous coating could be transformed in crystalline silicon dioxide without producing any substrate damages by conducting the second process step (b)) according to the present invention.

According to a further example an amorphous carbon coating (doped or non-doped, for example doped with Si or W) can be deposited in a process step a) by using a known VD process, such as PVD and/or CVD known processes, so that the amorphous carbon coating contains only or mainly carbon bound by sp2 hybridized bonds.

Subsequently the above mentioned amorphous carbon coating deposited in the process step a) is transformed in a process step b) in an amorphous carbon coating containing more sp3 hybridized bonds. It is possible because during the process step b) at least some of the sp2 hybridized bonds available in the coating deposited in the step a) are transformed into sp3 hybridized bonds, i.e. the amorphous carbon coating produced in step a) is at least partially transformed in the process step b) into carbon, which is bound by sp3 hybridized bonds.

According to one more further example, an amorphous aluminium oxide coating doped with one or more chemical elements, e.g. doped with titanium in a concentration between 0. 1 to 30 atomic percent, is deposited in a known manner in a process step a).

Subsequently the above mentioned Ti-doped amorphous aluminium oxide coating is transformed in process step b) into a non-amorphous or non-completely amorphous material consisting in a Ti-doped aluminium oxide exhibiting at least partially corundum crystalline structure.

Moreover, the above mentioned process step b) such treatment could be used for an heating of large coating parts, such as forming tool parts or components (such as turbine blades), which would occur outside a coating chamber (externally) prior to the coating process, to reduce heating time of such large parts.

1. A method for producing a coated substrate surface, comprising at least the following two process steps:
a) synthesizing a coating comprising at least one coating layer made of a first material (M₁) on a surface of a substrate to be coated, wherein the coating layer is produced by using a vapor deposition method, at a first temperature, with the first temperature not higher than 500° C., said first material (M₁) constituting the coating layer exhibiting a first set of physical properties (P_{f1}) and a first set of chemical properties (P_{ch1}), and
b) entering energy to the coating layer by applying a thermal treatment, which involves using at least one arc lamp operated in pulses, thereby heating the first material (M₁) with photons from the at least one arc lamp, thereby the first material (M₁) being irradiated and exposed to a specific high energy, wherein the specific high energy is selected in order to produce the same or an equivalent effect as would be attained if the coating layer were not produced at the first temperature but at a second temperature, wherein the second temperature is higher than the first temperature, hereby modifying the properties of the at least one coating layer deposited in process step a) and producing in this manner a thermal processed coating formed by at least one coating layer made of a second material (M₂), exhibiting a second set of physical properties (P_{f2}) and a second set of chemical properties (P_{ch2}), wherein the second materiel (M₂) differs from the first material (M₁) at least in the set of physical properties or at least in the set of chemical properties, so that P_{f1}≠P_{f2} and/or P_{ch1}≠P_{ch2}.

2. The method according to claim 1, wherein the vapor deposition process is a physical vapor deposition process or involves at least one physical vapor deposition process.

3. The method according to claim 1, wherein the vapor deposition process is a chemical vapor deposition process or involves at least one chemical vapor deposition process.

4. The method according to claim 1, wherein the vapor deposition process is a plasma assisted chemical vapor deposition process or involves at least one plasma assisted chemical vapor deposition process.

5. The method according to claim 1, wherein the at least one arc lamp is a flashlamp or a flashtube.

6. The method according to claim 1, wherein the second temperature is a temperature above 500° C.
